(19) United States
(12) Patent Application Publication
(10) Pub. No.: US 2007/0206364 A1
(43) Pub. Date: Sep. 6, 2007

(54) Methods of forming a flexible circuit board

(75) Inventors: Gwo Swei, Vandalia, OH (US); John R. Kastelic, Houston, TX (US); Paul W. Ortiz, Wayne, NJ (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: SAINT-GOBAIN PERFORMANCE PLASTICS CORPORATION, Aurora, OH (US)

(21) Appl. No.: 11/366,834

(22) Filed: Mar. 2, 2006

(51) Int. Cl. H05K 7/00; H05K 1/18

(52) U.S. Cl. 361/748

(57) ABSTRACT

A method for forming a flexible circuit board includes placing an adhesive coated coverlay over a flexible media, placing a release film over the adhesive coated coverlay and compressing together the flexible media, the adhesive coated coverlay, and the release film. The flexible media includes circuitry. The release film includes a multi-layer film having first and second layers. The first layer includes an elastomer and the second layer includes a fluoropolymer.

### FIELD OF THE DISCLOSURE

This disclosure, in general, relates to methods to form flexible circuit boards and relates to flexible circuit boards formed by such methods.

### BACKGROUND

With growing demand for portable consumer electronics, demand has increased for flexible circuit boards. Flexible circuit boards typically include circuitry printed on a flexible substrate. Such flexible circuit boards are useful in electronic devices, such as cell phones, portable digital assistants (PDA), and laptops. In particular, such flexible circuit boards are useful in portable electronic devices that have circuitry that moves relative to other electronic components of the portable electronic device. For example, flexible circuit boards are useful in electronic devices that include a screen that pivots relative to other device circuitry. Further, flexible circuit boards are useful in devices in which circuitry is contorted to fit the form of the device or in which the substrate of the circuitry may undergo torsion and vibration related stresses.

In general, flexible circuit boards include one or more layers of circuitry overlying one or more layers of substrates. The circuitry is often protected by an overlying coverlay that is adhesively coupled to the circuitry and the substrate. To facilitate communication with other electronic components and with power supplies, such flexible circuit boards typically include contact pads that are accessible through access holes in the coverlay. Adequate contact by other components and power supplies with the flexible circuit board circuitry may be prevented by misalignment of the access holes of the coverlay and the contact pads or may be prevented by adhesive overflow onto the contact pad. As such, the circuitry may malfunction or be completely inoperative.

Traditionally, great care is taken to align the coverlay access holes and the contact pads. In addition, manufacturers have employed manual methods for removing adhesive layers from contact pads. Such methods are time consuming and labor intensive. In addition, tools used in such methods may cause damage to underlying contact pads, reducing product quality and product yield.

As such, an improved method to manufacture flexible circuit boards and improved flexible circuit boards made through such methods would be desirable.

### SUMMARY

In a particular embodiment, a method of forming a flexible circuit board includes placing an adhesive coated coverlay over a flexible media, placing a release film over the adhesive coated coverlay and compressing together the flexible media, the adhesive coated coverlay, and the release film. The flexible media includes circuitry. The release film includes a multi-layer film having first and second layers. The first layer includes an elastomer and the second layer includes a fluoropolymer.

In another exemplary embodiment, a method of forming a flexible circuit board includes aligning a coverlay including an access hole and a flexible media having a conductive pad. The conductive pad is accessible through the access hole of the cover. The method also includes placing a release film over the coverlay to cover the access hole and compressing the release film, the coverlay and the flexible media. The release film includes first and second layers bonded directly to and directly contacting each other. The first layer includes an elastomer and the second layer includes a fluoropolymer.

In a further exemplary embodiment, a method of forming a flexible circuit board includes placing an adhesive coated coverlay over a flexible media, placing a release film over the adhesive coated coverlay, and compressing together and heating the flexible media, the adhesive coated coverlay, and the release film. The flexible media includes circuitry. The release film includes a multi-layer film having first and second layers bonded directly together. The release film has a conformity parameter not greater than 10%. The second layer contacts the adhesive coated coverlay.

In an additional embodiment, a flexible circuit board includes a flexible media including circuitry and a coverlay adhered to a major surface of the flexible media. The coverlay is adhered to a major surface of the flexible media by a method including placing the coverlay over the flexible media, placing a release film over the coverlay, and compressing together the flexible media, the coverlay, and the release film. The release film includes a multi-layer film having first and second layers. The first layer includes an elastomer and the second layer includes a fluoropolymer.

### BRIEF DESCRIPTION OF THE DRAWINGS

The present disclosure may be better understood, and its numerous features and advantages made apparent to those skilled in the art by referencing the accompanying drawings.

FIG. 1 includes an illustration of an exemplary embodiment of a flexible circuit board.

FIG. 2 includes an illustration of an exemplary apparatus to form a flexible circuit board.

FIG. 3 includes an illustration of an exemplary method to form a flexible circuit board.

FIG. 4 includes an illustration of an exemplary portion of a flexible circuit board, such as the flexible circuit board illustrated in FIG. 1.

FIG. 5 includes an illustration of an exemplary release film.

FIGS. 6 and 7 include graphs illustrating the compressibility of exemplary release films.

### DESCRIPTION OF THE DRAWINGS

In a particular embodiment, a flexible circuit board includes a coverlay adhered to a flexible media. The flexible media includes a substrate and circuitry formed on the substrate. In an exemplary embodiment, the coverlay is an adhesive coated coverlay, having adhesive coated on one major surface of the coverlay. The coverlay is adhered to the flexible media by a method including placing the coverlay over the flexible media, placing a release film over the coverlay, and compressing the flexible media, the coverlay, and the release film together. The release film, the coverlay, and the flexible media may also be heated. In an exemplary embodiment, adhesive is coated on a major surface of the coverlay. The adhesive melts or cures, adhering to the flexible media and forming a flexible media assembly. The release film may be separated from the flexible media assembly, which may be further processed to produce the flexible circuit board. In an exemplary embodiment, the release film is a multi-layer film including first and second layers. The first layer includes an elastomer and the second layer includes a fluoropolymer. In a particular embodiment, the first and second layers are in direct contact and are directly bonded together.

In an exemplary embodiment, the flexible media article includes a coverlay having an access hole to align with a contact pad of an underlying flexible media. FIG. 1 includes an illustration of an exemplary flexible media article 100 that includes a flexible media 102 having contact pads 108 and circuitry 110 in electrical communication with the contact pads 108. The circuitry 110 typically includes conductive lines providing electrical access between the contact pads 108 or between the contact pads 108 and other electronic components. The flexible media 102 typically includes a substrate film formed of a flexible polymeric material. An exemplary flexible polymeric material includes polyimide, polyester, or any combination thereof. An exemplary polyester includes polyethylene terephthalate.

The contact pads 108 and the circuitry 110 may be formed on the flexible polymeric substrate. An exemplary method to form the contact pads 108 and circuitry 110 includes coating the flexible polymeric substrate with a conductive metallic or ceramic material and etching a circuitry pattern into the conductive metallic or ceramic material. For example, the conductive pad 108 and the circuitry 110 may be formed of a metallic material, such as aluminum, copper, gold, silver, or any combination thereof. In another exemplary method, a metal or conductive ceramic film may be adhesively bonded in a desired pattern to the flexible substrate. Another method includes sputtering metallic material to form the circuitry 110 and the contact pads 108.

In an exemplary embodiment, the contact pads 108 and the circuitry 110 may be formed on a single side of the flexible media 102. Alternatively, the contact pads 108 or the circuitry 110 may be formed on both major surfaces of the flexible media 102. In a further exemplary embodiment, multiple layers of flexible media and the contact pads 108 and the circuitry 110 may be included to form a multi-layer flexible media 102. In a further alternative embodiment, rigid components may be adhered to flexible portions of the flexible media 102 to form a hybrid rigid/flexible printed circuit media.

A coverlay 104 may be adhesively coupled to a major surface of the flexible media 102. When assembled, the flexible media article 100 may include a single coverlay 104 overlying a major surface of the flexible media 102. In the illustrated embodiment, the flexible media article 100 includes a coverlay on each major surface of the flexible media 102. For example, the coverlay 104 is adhesively adhered to a first major surface of the flexible media 102 and a second coverlay 106 is adhesively adhered to a second major surface of the flexible circuit board 102. As used herein, the term “over” implies adjacent in a direction normal to a major surface. For example, as illustrated in FIG. 1, the coverlay 104 is over a first major surface of the flexible media 102 and the coverlay 106 is over a second major surface of the flexible media 102 regardless of the orientation of the flexible media 102. The coverlay 104 may include an access hole 112 that aligns with a conductive pad 108 to provide access to the conductive pad 108. For example, the conductive pads 108 are accessible through the access holes 112.

The coverlay 104 is typically formed of a flexible polymeric material, such as polyimide, polyester, or any combination thereof. For example, the coverlay may be formed of polyimide film. In another example, the coverlay 104 may be formed of a polyester film, such as a polyethylene terephthalate film.

In a particular embodiment, a major surface of the coverlay is coated with an adhesive. An exemplary adhesive includes an epoxy adhesive, an acrylic adhesive, a polyimide adhesive, or any combination thereof. In an example, the adhesive is a pressure sensitive adhesive. In another example, the adhesive is a heat activated adhesive. In an exemplary embodiment, the coverlay 104 includes adhesive coated on a surface that contacts the flexible media 102. Alternatively, an adhesive may be applied to the major surface of the flexible media 102 prior to overlaying the coverlay 104.

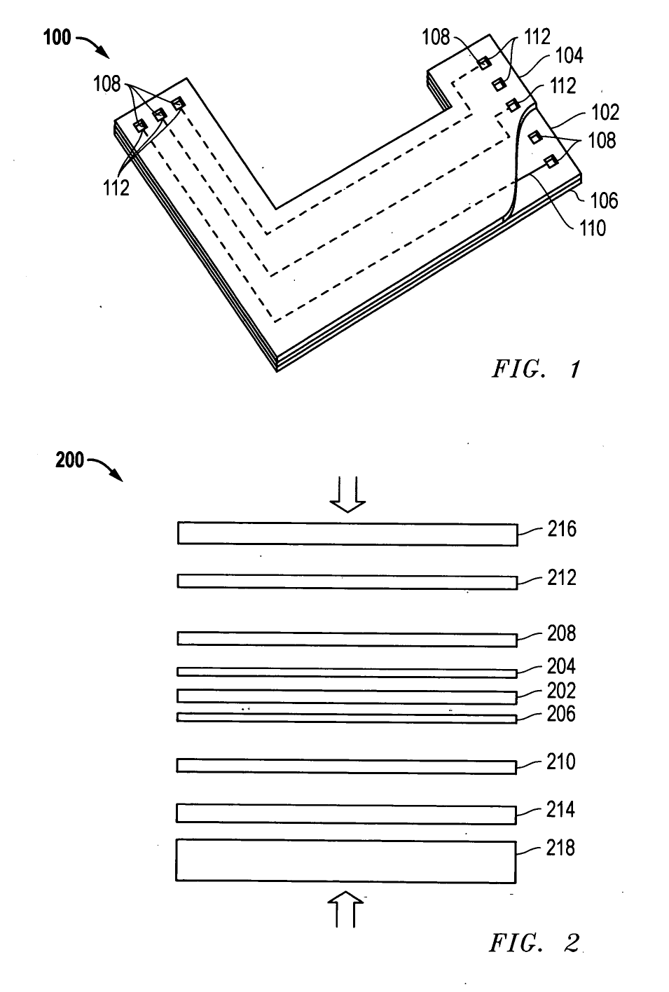

In general, the coverlay 104 and the flexible media 102 are compressed together and heated to form the flexible media article 100. For example, FIG. 2 includes an illustration of an exemplary apparatus 200 to form the flexible media assembly. In the illustrated example, a flexible media 202 may be placed between coverlays 204 and 206. For example, coverlays 204 and 206 may overlie opposite major surfaces of the flexible media 202. In a particular embodiment, the coverlays 204 and 206 are coated with an adhesive on a surface facing a major surface of the flexible media 202.

A release film 208 is placed over a major surface of the coverlay 204 opposite the major surface of the coverlay 204 contacting the flexible media 202. In an exemplary embodiment, the release film 208 is a multi-layer film including at least two layers. In an exemplary embodiment, the release film 208 includes a first layer formed of an elastomer and a second layer formed of a low surface energy polymer. For example, the elastomer may be a diene elastomer, such as an ethylene propylene diene monomer (EPDM) elastomer. The low surface energy polymer may be a fluoropolymer.

Optionally, an elastomeric film 212 may be placed over the release film 208. In an exemplary embodiment, the elastomeric film 212 is formed of a silicon-based elastomer or an EPDM elastomer. In a particular embodiment, the apparatus 200 is absent the optional elastomeric film 212 and the elastomeric film 214.

A platen 216 may be placed over the elastomeric film 212. In addition, a release film 210, the elastomeric film 214 and a platen 218 may be placed over the surface of the coverlay 206 opposite the major surface of the coverlay 206 that contacts the flexible media 202. The platens 216 and 218 and the films 204, 206, 208, 210, 212 and 214 may be compressed together. In an exemplary embodiment, the films may be heated. For example, platens 216 and 218 may be heated to heat the interlaying films. As a result, the coverlays 204 and 206 adhere to opposite major surfaces of the flexible media 202.

Typically, the coverlay is aligned with the flexible inedia such that access holes of the coverlay align with contact pads of the printed flexible media. When the release film is compressed with the coverlay and the flexible media, the release film conforms to the surface features of the coverlay and may extend into the access holes of the coverlay. When compressed, the adhesive of the coverlay flows and may flow over the contact pads. The release film may limit the flow of adhesive over the contact pads.

While the illustrated apparatus 200 is configured to form a flexible media assembly having coverlays 204 and 206 on opposite major surfaces of the flexible media 202, the apparatus 200 may also be configured to adhere a single layer on a single major surface of the flexible media. In an alternative embodiment, more than one set of films may be compressed together simultaneously. In such a method, more than one flexible media assembly may be formed during a single compression or heating step. For example, a set of flexible media, coverlays, and release films may be separated by platens from another set of flexible media, coverlays, and release films. In addition, alternative embodiments of the apparatus 200 include one or more additional elastomeric films, one or more additional release films, or one or more additional platens. In a further alternative embodiment, the apparatus may form flexible media assemblies without the elastomeric layers 212 and 214. For example, layers 212 and 214 may optionally be absent from the apparatus.

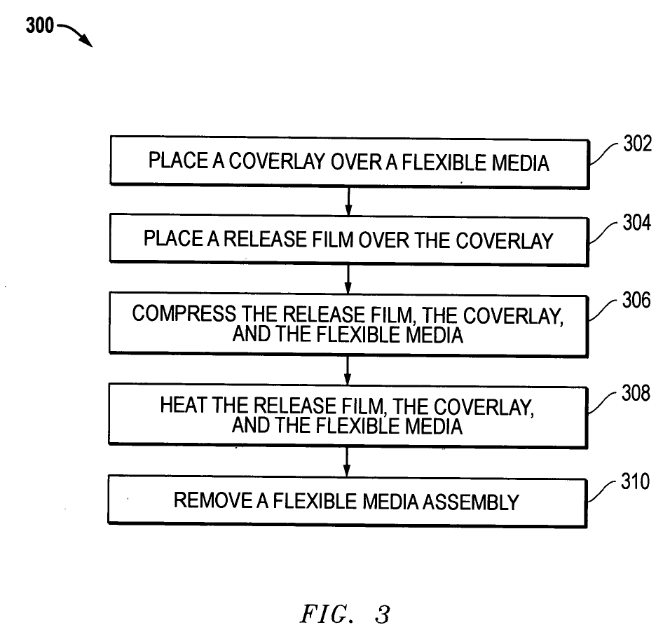

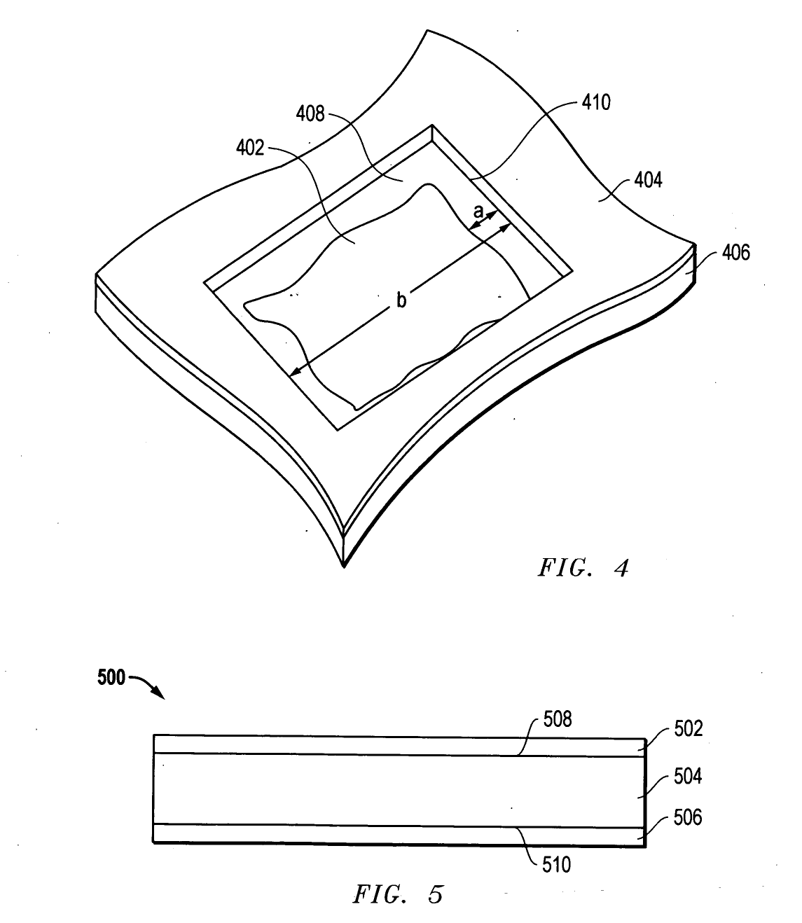

As illustrated in FIG. 3, a method 300 to form a flexible printed circuit board includes placing a coverlay over a flexible media, as illustrated at 302. For example, the coverlay may be placed over a first major surface of the flexible media. The coverlay may include an adhesive coated on the major surface of the coverlay that contacts the flexible media. In an alternative embodiment, an adhesive may be placed on the flexible media or the coverlay prior to placing the coverlay over the flexible media. Optionally, a second coverlay may be placed over a second major surface of the flexible media.

A release film is placed over the coverlay, as illustrated at 304. The release film may be, for example, a multi-layer film including at least two layers. For example, the multi-layer film may include two, three or more layers. In an exemplary embodiment, a first layer includes an elastomer and the second layer includes a low surface energy polymer. In a further embodiment, the first layer and the second layer are in direct contact and are directly bonded together. In a further example, a third layer including a low surface energy polymer may be bonded to and directly contact a major surface of the first layer opposite the major surface to which the second layer is bonded and with which the second layer directly contacts. In general, the layers including low surface energy polymer are outermost layers and may form release surfaces. As such, a release surface contacts the coverlay during compression.

The release film, the coverlay, and the flexible media are compressed together, as illustrated at 306. In addition, the release film, the coverlay, and the flexible media may be heated, as illustrated at 308. In an exemplary embodiment, a single layer elastomeric film may be placed over the release film and the single layer elastomeric film, the release film, the coverlay, and the flexible media placed between heated platens and compressed. In an alternative embodiment, the release film, the coverlay, and the flexible media may be compressed and heated absent the single layer elastomeric film. For example, when the coverlay includes a heat activated adhesive or when a thermally curing adhesive is applied between the coverlay and the flexible media, the flexible media assembly may be heated to activate the adhesive. As a result, the coverlay is adhered to the flexible media forming a flexible media assembly. The flexible media assembly may be separated from the release film and removed from the forming apparatus, as illustrated in 310. In addition, the flexible media assembly may be further processed to form a flexible printed circuit board.

When compressed and optionally heated, the adhesive between the coverlay and the flexible media may flow onto the contact pads of the flexible media. FIG. 4 includes an exemplary illustration of a contact pad 402 of a flexible media 406 accessible through an access hole of a coverlay 404. As illustrated, adhesive 408 extends over the contact pad 402 from an edge 410. During processing, a release film may be compressed to conform to the coverlay 404 and limit the flow of adhesive 408 over the contact pad 402.

The ability of the release film to conform to the contours and thus, the access holes of the coverlay 404 influences the flow of the adhesive 408 over the contact pads 402. In an exemplary embodiment, conformity may be indicated by the ratio of the distance “a” the adhesive 408 extends from the edge 410 over the contact pad and the shortest dimension “b” across an access hole of the coverlay in the plane of the major surface of the flexible media 406 and the contact pad 402.

In an exemplary method, a conformity parameter may be determined by testing a release film for conformity to a 1 mil (25 micron) thick polyimide coverlay having a 13 micron adhesive layer and a 1 millimeter across access hole in the form of a square. The release film, the coverlay, and an underlying substrate are compressed together at a temperature of about 170° C. and a pressure of 150 kg/cm² for a period of sixty minutes. A conformity parameter is determined as a ratio of an average distance of the adhesive leakage from the edge of the access hole and the cross section distance of the access hole, herein 1 millimeter. In a particular embodiment, the release film exhibits a conformity parameter of not greater than about 10%. For example, the conformity parameter may be not greater than about 6%, such as not greater than about 4%.

FIG. 5 includes an illustration of an exemplary release film 500. The exemplary release film 500 includes an elastomeric layer 504 having a first major surface 508. The layer 504 may include a major surface 508 over which lies a layer 502. In an exemplary embodiment, the layer 502 includes a low-surface energy polymer. In another exemplary embodiment, the layer 502 is bonded directly to and directly contacts the major surface 508 of the elastomeric layer 504. For example, the layer 502 and the layer 504 are bonded directly, without an intervening adhesive layer.

In a particular embodiment, the multi-layer film includes two layers 504 and 502. In the illustrated embodiment, the multi-layer film includes three layers. For example, the multi-layer film optionally may include a layer 506. The layer 506 may overlie a major surface 510 of the layer 504. In an exemplary embodiment, the layer 506 includes a low-surface energy polymer. In a further embodiment, the multi-layer film may include more than three layers.

In an exemplary embodiment, the multi-layer film has a thickness at least about 13 microns, such as at least about 25 microns. For example, the multi-layer film may have a thickness at least about 50 microns, at least about 100 microns, or as high as 200 microns or higher.

The layer 502 includes a low surface energy polymer and exhibits desirable release characteristics. In an exemplary embodiment, the low surface energy polymer is a thermoplastic polymer that is melt processable. In an alternative embodiment, the polymer may be formed by deposition and sintering. In a particular embodiment, the low surface energy polymer includes a fluoropolymer. An exemplary fluoropolymer includes a fluorinated copolymer of ethylene and propylene (FEP), a copolymer of tetrafluoroethylene and perfluoropropylvinyl ether (PFA), a copolymer of tetrafluoroethylene and perfluoromethyl vinyl ether (MFA), a copolymer of ethylene and tetrafluoroethylene (ETFE), a copolymer of ethylene and chlorotrifluoroethylene (ECTFE), polychlorotrifluoroethylene polymer (PCTFE), polyvinylidine fluoropolymer (PVDF), a terpolymer containing segments of tetrafluoroethylene, hexafluoropropylene and vinylidene fluoride (THV), or blends or alloys thereof. In a particular example the fluoropolymer includes FEP. In an exemplary embodiment, the fluoropolymer may be crosslinkable, for example, capable of undergoing crosslinking. Of the above thermoplastic fluoropolymers, ETFE, THV and PVDF can be crosslinked, for example, by radiation, such as e-beam radiation. Alternatively, the fluoropolymer may not be crosslinkable. A THV resin is available from Dyneon 3M Corporation Minneapolis, Minn. An ECTFE polymer is available from Ausimont Corporation (Italy) under the trade name Halar. Other fluoropolymers used herein may be obtained from Daikin (Japan) and DuPont (USA). In particular, FEP fluoropolymers are commercially available from Daikin, such as NP-12X.

The elastomeric layer 504 may be formed of an elastomeric polymer. For example, the elastomeric layer 504 may include a silicone, a polyolefin, a diene elastomer, or any combination thereof. In particular, the elastomeric layer may include a homopolymer, a copolymer, a terpolymer, or any mixture thereof. An exemplary polyolefin includes high-density polyethylene (PE), medium-density PE, low-density PE, ethylenepropylene copolymers, ethylene-butene-1 copolymer, polypropylene (PP), polybutene-1, polypentene-1, poly-4-methylpentene-1, ethylene-propylene rubber (EPR), or any combination thereof. An exemplary diene elastomer includes a copolymer of ethylene, propylene, and diene monomer (EPDM). In a particular example, the EPDM polymer may include interpolymerized units of ethylene, propylene and diene monomers. Ethylene may constitute from about 63 wt % to about 95 wt % of the polymer, propylene from about 5 wt % to about 37 wt %, and the diene from about 0.2 wt % to about 15 wt %, all based upon the total weight of EPDM polymer. In a particular example, the ethylene content is from about 70 wt % to about 90 wt %, propylene from about 17 wt % to about 31 wt %, and the diene from about 2 wt % to about 10 wt % of the EPDM polymer. An exemplary diene monomer includes a conjugated diene, such as butadiene, isoprene, chloroprene, or the like; a non-conjugated diene including from 5 to about 25 carbon atoms, such as 1,4-pentadiene, 1,4-hexadiene, 1,5-hexadiene, 2,5-dimethyl-1,5-hexadiene, 1,4-octadiene, or the like; a cyclic diene, such as cyclopentadiene, cyclohexadiene, cyclooctadiene, dicyclopentadiene, or the like; a vinyl cyclic ene, such as 1-vinyl-1-cyclopentene, 1-vinyl-1-cyclohexene, or the like; an alkylbicyclononadiene, such as 3-methylbicyclo-(4,2,1)-nona-3,7-diene, or the like; an indene, such as methyl tetrahydroindene, or the like; an alkenyl norbomene, such as 5-ethylidene-2-norbomene, 5-butylidene-2-norbomene, 2-methallyl-5-norbomene, 2-isopropenyl-5-norbomene, 5-(1,5-hexadienyl)-2-norbomene, 5-(3,7-octadienyl)-2-norbomene, or the like; a tricyclodiene, such as 3-methyltricyclo (5,2,1,0²,6)-deca-3,8-diene or the like; or any combination thereof. In a particular embodiment, the diene includes a non-conjugated diene. In another embodiment, the diene elastomer includes alkenyl norbomene. The diene elastomer typically has a Mooney viscosity of at least about 20, such as about 25 to about 150 (ML 1+8 at 125° C.). In an exemplary embodiment, the diene elastomer has a dilute solution viscosity (DSV) of at least about 1, such as about 1.3 to about 3 measured at 25° C. as a solution of 0.1 gram of diene polymer per deciliter of toluene. Prior to crosslinking, the diene elastomer may have a green tensile strength of about 800 psi to about 1,800 psi, such as about 900 psi to about 1,600 psi. The uncrosslinked diene elastomer may have an elongation at break of at least about 600 percent. In general, the EPDM polymer includes a small amount of a diene monomer, such as a dicyclopentadiene, a ethylnorbomene, a methylnorbornene, a non-conjugated hexadiene, or the like, and typically have a number average molecular weight of from about 50,000 to about 100,000. Exemplary diene elastomers are commercially available under the tradename Nordel from Dow Dupont.

In an exemplary embodiment, the elastomer of the elastomeric layer 504 is crosslinkable. For example, the elastomer may be thermally crosslinked or crosslinked using radiation. In a particular example, crosslinking can be effected by radiation. Such radiation may include X-rays, gamma rays, ultraviolet, visible light or electron beam, also known as e-beam. Ultraviolet (UV) radiation may include radiation at a wavelength or a plurality of wavelengths in the range of from 170 to 400 nm. Ionizing radiation includes high energy radiation capable of generating ions and includes electron beam radiation, gamma rays and x-rays. In a particular example, e-beam ionizing radiation includes an electron beam generated by a Van de Graaff generator, an electron-accelerator or an x-ray.

In an exemplary embodiment, the layer 502 and the layer 504 directly contact and are directly bonded together. For example, the layer 502 and the layer 504 are directly bonded together without intervening adhesive. Alternatively, an adhesive may lie between the layers 502 and 504. The multi-layer film 500 may be formed through co-extrusion, co-lamination, extrusion-lamination, melt coating of a preformed layer or co-molding. With respect to co-molding, the co-molding can be by co-injection molding, multi-material molding, multi-shot molding, transfer molding, blow molding, or compression molding including multilayer compression molding. Alternatively, the multilayer film may be formed through sequential coating involving any combination of solution coating or emulsion coating. Multilayers may be built up of deposits of such coated layers applied by any of the conventional means for attaining thin layers such as dipping, spreading, doctoring or any form of roll coating.

In particular, co-extrusion may produce a film or sheet. For example, a sheet of each layer 502, 504, and optionally 506 may be extruded and placed together while in a heat-softened condition in the co-extrusion die or after the outlet of the die to form a pre-formed article. When chemical crosslinkers are present, crosslinking may occur. Alternatively, the sheet may be subjected to radiation crosslinking.

Once the multilayer article is pre-formed, crosslinking may be performed to bond the layers 502, 504, and optionally 506 together. Such crosslinking may alter mechanical properties of the eleastomeric layer 504 and improve peel strength between the layers 502, 504, and 506. Crosslinking may be performed at elevated temperature, such as when the layers 502, 504, and 506 are placed together at above the melting point of either component, at room temperature, or at any temperature in between.

To facilitate crosslinking, the material of the elastomeric layer 504 may include a photoinitiator or a sensibilizer composition. For example, when ultra-violet radiation is contemplated as the form of irradiation or when e-beam radiation is contemplated as the form of irradiation, the material may include a photoinitiator to increase the crosslink efficiency, i.e., degree of crosslink per unit dose of radiation.

An exemplary photoinitiator includes benzophenone, ortho- and para-methoxybenzophenone, dimethylbenzophenone, dimethoxybenzophenone, diphenoxybenzophenone, acetophenone, o-methoxy-acetophenone, acenaphthene-quinone, methyl ethyl ketone, valerophenone, hexanophenone, alpha-phenyl-butyrophenone, p-morpholinopropiophenone, dibenzosuberone, 4-morpholinobenzo-phenone, benzoin, benzoin methyl ether, 3-o-morpholinodeoxybenzoin, p-diacetyl-benzene, 4-aminobenzophenone, 4′-methoxyacetophenone, alpha-tetralone, 9-acetylphenanthrene, 2-acetyl-phenanthrene, 10-thioxanthenone, 3-acetyl-phenanthrene, 3-acetylindole, 9-fluorenone, 1-indanone, 1,3,5-triacetylbenzene, thioxanthen-9-one, xanthene-9-one, 7-H-benz[de]anthracen-7-one, benzoin tetrahydrophyranyl ether, 4,4′-bis(dimethylamino)-benzophen 1′-acetonaphthone, 2′acetonaphthone, aceto-naphthone and 2,3-butanedione, benz[a]anthracene-7,12-dione, 2,2-dimethoxy-2-phenylaceto-phenone, alpha-diethoxy-acetophenone, alpha-dibutoxy-acetophenone, anthraquinone, isopropylthioxanthone, or any combination thereof. An exemplary polymeric initiator may include poly(ethylene/carbon monoxide), oligo[2-hydroxy-2-methyl-1-[4-(1-methylvinyl)-phenyl]propanone], polymethylvinyl ketone, polyvinylaryl ketones, or any combination thereof.

Another exemplary photoinitiator includes benzophenone; anthrone; xanthone; the Irgacure® series of photoinitiators from Ciba-Geigy Corp., including 2,2-dimethoxy-2-phenylac-etophenone (Irgacure® 651), 1-hydroxycyclohexylphenyl ketone (Irgacure® 184), 2-methyl-1-[4-(methylthio)phenyl]-2-moropholino propan-1-one (Irgacure® 907); or any combination thereof. Generally, the photoinitiator exhibits low migration from the material of the elastomeric layer 504. In addition, the photoinitiator typically has a low vapor pressure at extrusion temperatures and sufficient solubility in the polymer or polymer blends of the elastomeric layer 504 to yield efficient crosslinking. In an exemplary embodiment, the vapor pressure and solubility, or polymer compatibility, of the photoinitiator may be improved by derivatizing the photoinitiator. An exemplary derivatized photoinitiator includes, for example, higher molecular weight derivatives of benzophenone, such as 4-phenylbenzophenone, 4-allyloxybenzophenone, 4-dodecyloxybenzophenone or any combination thereof. In an example, the photoinitiator may be covalently bonded to a polymer of the material of the elastomeric layer 504.

In an exemplary embodiment, the material of the elastomeric layer 504 includes about 0.0 wt % to about 3.0 wt % photoinitiator, such as about 0.1 wt % to about 2.0 wt % or about 0.25 wt % to about 1.0 wt %.

Crosslinking may also be facilitated by a chemical crosslinking initiator or agent, such as a peroxide, an amine, a silane, or any combination thereof. In an exemplary embodiment, the material of the elastomeric layer 504 may be prepared by dry blending solid state forms of polymer and the crosslinking agent, i.e., in powder form. Alternatively, the material may be prepared in liquid form, sorbed in inert powdered support or by preparing coated pellets, or the like.

An exemplary thermally activatable crosslinking agent includes a free radical generating chemical, which when exposed to heat decompose to form at least one, and typically two or more free radicals to affect crosslinking. In an exemplary embodiment, the crosslinking agent is an organic crosslinking agent including an organic peroxide, an amine, a silane, or any combination thereof. In a particular example, an organic peroxides may act as a chemical initiator to initiate crosslinking between another crosslinking agent and a crosslinkable polymer. Organic peroxides often may be activated by heat or chemical reaction and initiate a crosslinking reaction through formation of radicals. In another example, a crosslinking agent may include a reactive ingredient that facilitates and participates in the formation of crosslinks. For example, a crosslinking agent may have an unsaturated group that forms a crosslink with functional groups of the crosslinkable polymer.

An exemplary organic peroxide includes 2,7-dimethyl-2,7-di(t-butylperoxy)octadiyne-3,5; 2,7-dimethyl-2,7-di(peroxy ethyl carbonate)octadiyne-3,5; 3,6-dimethyl-3,6-di(peroxy ethyl carbonate)octyne-4; 3,6-dimethyl-3,6-(t-butylperoxy)octyne-4; 2,5-dimethyl-2,5-di(peroxybenzoate)hexyne-3; 2,5-dimethyl-2,5-di(peroxy-n-propyl carbonate)hexyne-3; 2,5-dimethyl-2,5-di(peroxy isobutyl carbonate)hexyne-3; 2,5-dimethyl-2,5-di(peroxy ethyl carbonate)hexyne-3; 2,5-dimethyl-2,5-di(alpha-cumyl peroxy)hexyne-3; 2,5-dimethyl-2,5-di(peroxy beta-chloroethyl carbonate) hexyne-3; 2,5-dimethyl-2,5-di(t-butylperoxy) hexyne-3; or any combination thereof. A particular crosslinking agent is 2,5-dimethyl-2,5-di(t-butyl peroxy)hexyne-3, available from Elf Atochem under the trade designation Lupersol 130. Another exemplary crosslinking agent is dicumyl peroxide, available from Elf Atochem as Luperox 500R. In a particular embodiment, the crosslinking agent is present in the material in an amount between about 0.1 wt % to about 5.0 wt %, such as about 0.5 wt % to about 2.0 wt % based on the weight of the material.

An exemplary silane crosslinking agent has the general formula:

in which R1 is a hydrogen atom or methyl group; x and y are 0 or 1 with the 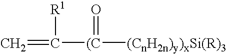
proviso that when x is 1, y is 1; n is an integer from 1 to 12, preferably 1 to 4, and each R independently is a hydrolyzable organic group such as an alkoxy group having from 1 to 12 carbon atoms (e.g., methoxy, ethoxy, butoxy), aryloxy group (e.g., phenoxy), araloxy group (e.g., benzyloxy), aliphatic acyloxy group having from 1 to 12 carbon atoms (e.g., formyloxy, acetyloxy, propanoyloxy), amino or substituted amino groups (e.g., alkylamino, arylamino), or a lower alkyl group having 1 to 6 carbon atoms, with the proviso that not more than one of the three R groups is an alkyl. Such silanes may be grafted to a polymer through the use of an organic peroxide. Additional ingredients such as heat and light stabilizers, pigments, or any combination thereof, also may be included in the material. In general, the crosslinking reaction may result from a reaction between the grafted silane groups and water. Water may permeate into the bulk polymer from the atmosphere or from a water bath or “sauna”. An exemplary silane includes an unsaturated silane that comprise an ethylenically unsaturated hydrocarbyl group, such as a vinyl, allyl, isopropenyl, butenyl, cyclohexenyl or gamma-(meth)acryloxy allyl group, and a hydrolyzable group, such as, for example, a hydrocarbyloxy, hydrocarbonyloxy, or hydrocarbylamino group. An example of a hydrolyzable group includes a methoxy group, an ethoxy group, a formyloxy group, an acetoxy group, a proprionyloxy group, an alkyl group, an arylamino group, or any combination thereof. A particular silane is an unsaturated alkoxy silanes that can be grafted onto the polymer. In particular, the silane may include vinyl trimethoxy silane, vinyl triethoxy silane, gamma-(meth)acryloxy propyl trimethoxy silane, or any combination thereof.

The amount of silane crosslinker may vary widely depending upon the nature of the thermoplastic polymer, the silane, the processing conditions, the grafting efficiency, the ultimate application, and similar factors. Typically, at least 0.5 parts per hundred resin (phr), such as at least about 0.7 phr, is used. Generally, the amount of silane crosslinker does not exceed 5 phr, such as not greater than about 2 phr.

In another exemplary embodiment, an amine crosslinking agent may include a monoalkyl, duallyl or trialkyl monoamine, wherein the alkyl group contains from about 2 to about 14 carbon atoms; a trialkylene diamine of the formula N(R²)₃N; a dialkylene diamine of the formula HN(R²)₂NH; an alkylene diamine, H₂NR²NH₂; a dialkylene triamine, H₂NR²NHR²NH₂; an aliphatic amine having a cyclic chain of from four to six carbon atoms; or any combination thereof. The alkylene group R² in the above formulae may include from about 2 to about 14 carbon atoms. An exemplary cyclic amine may have a heteroatom, such as oxygen, for example, an N-alkyl morpholine. Another exemplary cyclic amine includes pyridine, N,N-dialkyl cyclohexylamine, or any combination thereof. An exemplary amine is triethylamine; di-n-propylamine; tri-n-propylamine; n-butylamine; cyclohexylamine; triethylenediamine; ethylenediamine; propylenediamine; hexamethylenediamine; N,N-diethyl cyclohexylamine; pyridine; or any combination thereof. In an exemplary embodiment, the material includes from about 0.5 wt % to about 10.0 wt % of the amine.

To illustrate crosslinking by radiation, a film is prepared by the extrusion process. In the extrusion process, the material of layer 502, the material of layer 504, and optionally, the material of layer 506 may be separately melted and separately supplied or jointly melted and supplied to a co-extrusion feed block and die head wherein a film including the layers 502, 504, and optionally 506 is generated. An exemplary die employs a “coat hanger” type configuration.

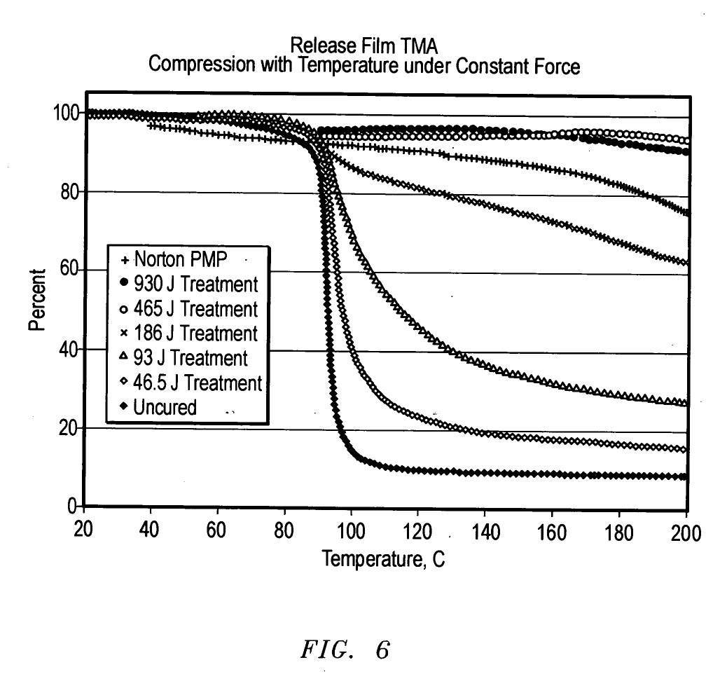

Once the film is formed, radiation crosslinking may be immediately performed and the film may be rolled. Alternatively, the film may be rolled in an uncrosslinked state, unrolled at a later time and subjected to radiation crosslinking. In an alternative example, the film is not cured and remains uncured or uncrosslinked. In a further example, the film is partially cured. In exemplary films including an intermediate layer having EPDM, high crosslinking is indicated by a relatively flat profile of the compressive strain curve at temperatures at least 75° C. higher than the temperature at which an uncured sample exhibits a maximum in absolute value rate of change of compressive strain relative to temperature. Partially crosslinked samples exhibit profiles that fall between the uncured and highly cured samples on a compressive strain versus temperature graph. See, for example, FIG. 6 as described below.

The radiation may be effective to create crosslinks in the crosslinkable polymer of the layer 104. The “intracrosslinking” of polymer molecules within the layer 104 provides a cured or partially cured composition and imparts added structural strength to the layer 104 of the multi-layer film 100, particularly at elevated temperatures. Additionally, the modulus at normal and elevated temperatures may be increased by the crosslinking of the material of layer 104. In particular, crosslinking can be controlled to provide a desirable compressive strain in the compressive strain versus temperature graph or a desirable conformity in the lamination process. In some lamination cycles and processes, partly cured films surprisingly may exhibit a lower conformity parameter compared to more highly cured or highly crosslinked films.

In a particular embodiment, the combination of intercrosslinking bonds between the layers and the cured core layer present an integrated composite that is sufficiently resistant to delamination, has a high quality adhesion resistant and protective surface, incorporates a minimum amount of adhesion resistant material, and yet, is physically substantial for convenient handling and deployment of the multilayer film 100 and for satisfactory retention of integrity in the circuit lamination process.

### EXAMPLES

Sample films are tested for compressibility at various temperatures using a VICAT probe having a flat head, 1 mm in diameter. The probe is pressed onto a flat film sample using 1000 millineuton force and the compressive strain is measured during compression and while the sample film is heated.

### Example 1

Sample films are coextruded and include two 0.2 mil outermost layers formed of Daikin NP-12X FEP and a single intermediate layer between the outermost layers formed of Nordel 4820 EPDM. The total film thickness is 2.0 mils. The samples are cured using various doses of ultraviolet radiation generated by an H+ bulb included in a Fusion UV Systems Model VPS-6 system. The blends did not include a photoinitiator.

FIG. 6 includes a graph of the exemplary films exposed to 0 J, 46.5 J, 93 J, 186 J, 465 J, and 930 J, respectively. Increased exposure to ultraviolet radiation results in increased crosslinking. The films are compared to a film formed of polymethylpentene. In general, less exposure leads to a reduction in percent thickness during compression at lower temperatures. The polymethylpentene film exhibits a small change in the percent thickness within the temperature range illustrated.

### Example 2

Sample films are coextruded and include two 0.2 mil outermost layers formed of Daikin NP-12X FEP and a single intermediate layer between the outermost layers formed of Nordel 4820 EPDM. The samples are cured using various doses of ultraviolet radiation generated by an H+ bulb included in a Fusion UV Systems Model VPS-6 system. The blends did not include a photoinitiator.

The FLE-2125 sample represents a film having a total thickness of 2 mils coextruded and exposed to ultraviolet radiation at a low line speed, increasing crosslinking. The FLE-5125 and FLE-5150 samples represent films having a total thickness of 5 mils. The FLE-5125 sample is coextruded and exposed to ultraviolet radiation at a low line speed and the FLE-5150 sample is coextruded and exposed to ultraviolet radiation at an increased line speed. The samples are compared to commercially available release films formed of other materials, such as polymethylpentene.

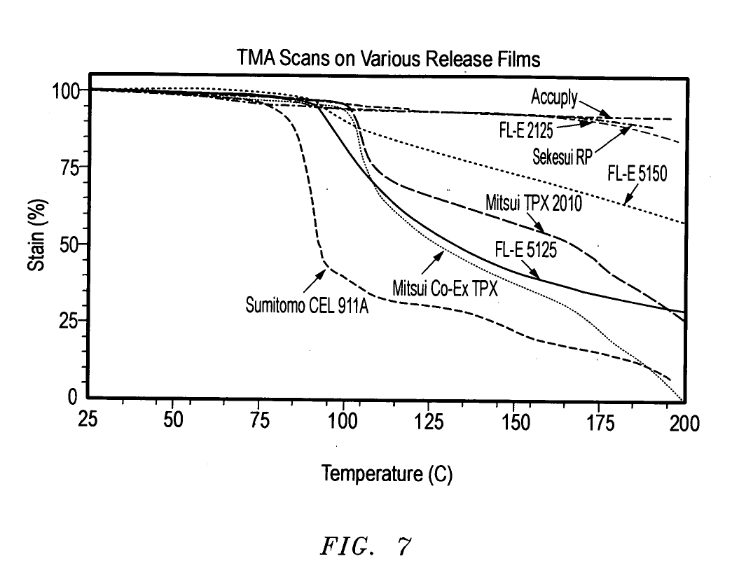

FIG. 7 includes a graph of the compressive strain relative to temperature for the sample films and the commercially available films. As illustrated, the strain performance of the exemplary sample films may be adjusted to match other commercially available films by altering thickness and curing parameters.

Particular embodiments of the method advantageously improve flexible circuit board quality and yield. For example, particular embodiments of the method reduce adhesive flow over contact pads, improving contact with such contact pads and reducing additional processing associated with cleaning contact pads. In another example, particular embodiments of the method provide improved yields by reducing wrinkles and tears in flexible circuit boards.

The above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

1. A method of forming a flexible circuit board, the method comprising:
placing an adhesive coated coverlay over a flexible media, the flexible media comprising circuitry;
placing a release film over the adhesive coated coverlay, the release film comprising a multilayer film having first and second layers, the first layer comprising an elastomer and the second layer comprising a fluoropolymer; and
compressing together the flexible media, the adhesive coated coverlay, and the release film.

2. The method of claim 1, wherein placing the release film over the adhesive coated coverlay includes placing the second layer of the release film in contact with the adhesive coated coverlay.

3. The method of claim 1, wherein compressing together includes compressing together the flexible media, the adhesive coated coverlay, and the release film, excluding a single layer elastomer film.

4. The method of claim 1, wherein the elastomer comprises a diene elastomer.

5. The method of claim 4, wherein the diene elastomer comprises ethylene propylene diene monomer (EPDM) elastomer.

6. The method of claim 1, wherein the fluoropolymer comprises fluorinated ethylene propylene (FEP) polymer.

7. The method of claim 1, further comprising heating the flexible media, the adhesive coated coverlay, and the release film.

8. The method of claim 7, wherein heating and compressing are performed concurrently.

9. The method of claim 1, wherein the flexible media and the adhesive coated overlay adhere together to form a flexible media assembly, the method further comprising separating the release film and the flexible media assembly.

10. The method of claim 1, wherein the release film has a conformity parameter of not greater than about 10%.

11. The method of claim 10, wherein the conformity parameter is not greater than about 6%.

12. (canceled)

13. The method of claim 1, wherein the elastomer is uncured.

14. The method of claim 1, wherein the elastomer is partially crosslinked.

15. The method of claim 1, wherein the elastomer is highly crosslinked.

16. A method of forming a flexible circuit board, the method comprising:
aligning a coverlay having an access hole and a flexible media having a conductive pad, the conductive pad accessible through the access hole of the coverlay;
placing a release film over the coverlay to cover the access hole, the release film comprising first and second layers bonded directly to and directly contacting each other, the first layer comprising an elastomer and the second layer comprising a fluoropolymer; and
compressing the release film, the coverlay, and the flexible media.

17. The method of claim 16, wherein the coverlay includes a first major surface coated with an adhesive.

18-22. (canceled)

23. The method of claim 16, further comprising heating the release film, the coverlay, and the flexible media.

24. The method of claim 16, wherein the release film has a conformity parameter not greater than 10%.

25. A method of forming a flexible circuit board, the method comprising:
placing an adhesive coated coverlay over a flexible media, the flexible media comprising circuitry;
placing a release film over the adhesive coated coverlay, the release film comprising a multilayer film having first and second layers bonded together, the release film having a conformity parameter of at least about 10%, the second layer contacting the adhesive coated coverlay; and
compressing together and heating the flexible media, the adhesive coated coverlay, and the release film.

26-31. (canceled)
